(19) United States
(12) Patent Application Publication
(10) Pub. No.: US 2024/0258345 A1
(43) Pub. Date: Aug. 1, 2024

(54) SEMICONDUCTOR PACKAGE IN CAMERA MODULE

(71) Applicant: ZINITIX CO., LTD., Gyeonggi-do (KR)

(72) Inventors: Kyoung Won HYUN, Gyeonggi-do (KR); Dong Won KIM, Gyeonggi-do (KR)

(21) Appl. No.: 18/289,620

(22) PCT Filed: Jun. 25, 2021
(86) PCT No.: PCT/KR2021/007999

§ 371 Date: Nov. 6, 2023

(30) Foreign Application Priority Data
May 6, 2021 (KR) 10-2021-0058848

(51) Int. Cl. H01L 27/146

(52) U.S. Cl. CPC H01L 27/14618; H01L 27/14625

(57) ABSTRACT

Disclosed is a wafer-level chip-size package type semiconductor package having a plurality of terminals, wherein the semiconductor package has an elongated rectangular planar shape, the plurality of terminals is configured with two column arranged in the short-side direction of the semiconductor package, and each terminal comprises a circular body part and a protruding part extending outward from the body part.

### TECHNICAL FIELD

The present invention relates to a semiconductor package in a camera module, and more particularly, to a shape of a semiconductor package for increasing in amount of lead of the semiconductor package.

### BACKGROUND ART

FIGS. 1A and 1B are views for explaining a camera module according to an embodiment.

FIG. 1A is a perspective view of the camera module 1, and FIG. 1B is a perspective view illustrating a side surface of a housing 4 from which a lens assembly 21 is removed from the camera module 1.

The camera module 1 may be, for example, a camera module including a smartphone or a mobile phone.

An assembly 21 of a lens 2 may be disposed at a center of the camera module 1. Referring to FIG. 1B, a semiconductor package 3 and a coil 5 may be installed on an inner wall of the housing 4 of the camera module 1 from which the lens assembly 21 is removed from the camera module 1. For example, the semiconductor package 3 may be a VCM driving chip.

Here, the lens assembly 21 may include a lens and a barrel.

FIGS. 2A-2D are views illustrating constraints in lens aperture of the camera module and size of the semiconductor package according to an embodiment.

FIG. 2A is a plan view of the camera module 1, FIG. 2B is a view for explaining an aperture of the lens, FIG. 2C is an enlarged view illustrating only the semiconductor package illustrated in FIG. 1B, i.e., a view illustrating a surface on which a coil is disposed inside the camera module housing 4, and FIG. 2D is a view illustrating a surface on which a lead ball of the semiconductor package is disposed.

Hereinafter, description will be made with reference to FIGS. 1 and 2.

A plurality of circular pads (not shown) for coupling the semiconductor package 3 may be disposed on a PCB installed on the wall of the camera module housing 4.

In addition, referring to FIG. 2D, for example, six lead balls (or terminals, which will be referred to as terminals) may be disposed on the semiconductor package 3. Here, an interval between the lead balls 31 and a position and shape of each lead ball 31 may correspond to an interval between the plurality of pads and a position and shape of each pad. For example, each of the lead balls and the pads may generally have a circular shape.

A state in which lead is disposed on one surface of the semiconductor package 3 (i.e., state in which the lead ball is disposed) may be a semiconductor package as a finished product.

Here, it is necessary to increase in amount of lead of the lead ball 31 of the semiconductor package 3. For this, a method for increasing in height of the lead ball 31 may be used.

However, referring to FIGS. 2A and 2B, as an aperture Lens_d of the lens 2 gradually increases recently, a reference symbol w1 that represents a minimum interval between one side of the camera module 1, i.e., one side of the wall of the housing 4 and one point of the lens 2 may be reduced in size.

Thus, as illustrated in FIG. 2C, since a vertical length h1 of the semiconductor package 3 (hereinafter, the vertical length includes the height of the lead ball) is restricted in increase, a height of the lead ball 31 is restricted in increase as illustrated in FIG. 2D. That is, when the height of the lead ball 31 is limited to a certain height, there is a limitation that the above method is not used.

Alternatively, there may be a method of increasing in diameter of the circular pad.

However, an overall height H of the camera module 1 illustrated in FIG. 1B has recently been decreasing, and as illustrated in FIG. 2C, since a short axis h2 of the semiconductor package 3 has to be reduced to secure an area of the coil 5, a diameter of the lead ball 31 is restricted in increase.

In addition, since a minimum distance between the PCB and the pad is restricted, a limitation may occur. That is, when the diameter of the pad increases, since sizes increase in all directions, the minimum distance between the pads that has to be satisfied may not be satisfied.

### DISCLOSURE OF THE INVENTION

### Technical Problem

The present invention is to provide a semiconductor package that increases in amount of lead of a lead ball of the semiconductor package while satisfying a minimum distance between pads.

### Technical Solution

According to one aspect of the prevent invention, provided is a semiconductor package 10 provided as a wafer-level chip-size package type semiconductor package having a plurality of terminals 100 and 200. The semiconductor package may have an elongated and narrow rectangular planar shape, the plurality of terminals may be arranged in two columns along a short-side direction D1 of the semiconductor package, and each of the terminals may include a circular body part 111 and a protruding part 112 extending outward from the body part.

Here, the protruding part may include a first straight edge line 112a, and an extension line L1 of the first straight edge line may pass through a gravity center 113 of the body part. In addition, the protruding part may be disposed in a counterclockwise direction based on the first straight edge line.

Here, the protruding part may include a first straight edge line, and an extension line of the first straight edge line may pass through a gravity center of the body part. In addition, the protruding part may be disposed in a clockwise direction based on the first straight edge line.

Here, in a virtual straight radial line L11 connected from a gravity center 12 of the semiconductor package to the gravity center of the body part of each of the plurality of terminals, an angle between a first direction LD11, in which the virtual straight radial line is directed, and a protruding direction of the protruding part of the terminal, through which the straight radial line passes, may be greater than about 45° and less than about 165°.

Here, the protruding part may further include a second straight edge line 112b and a third straight edge line 112c. In addition, the third straight edge line may be parallel to the first straight edge line, and one end point of the third straight edge line may be connected to one point of the body part. In addition, both end points of the second straight edge line may be connected to a point of both end points of the first straight edge line 112a, which is not connected to the body part, and the other end point of the third straight edge line 112c so that a shape of the protruding part is symmetrical to a ‘C’ shape, respectively.

Here, the protruding part may further include a fourth curved edge line 112d. In addition, one end point of the fourth curved edge line may be connected to a point of both end points of the first straight edge line, which is not connected to the body part, and the other end point of the fourth curved edge line may be connected to one point of the body part.

Here, the protruding part 112 of at least one terminal 110 of the plurality of terminals may be configured to invade a virtual division line 11 that divides the plurality of terminals into two columns in the semiconductor package.

### Advantageous Effects

According to the present invention, the semiconductor package that increases in amount of lead of the lead ball of the semiconductor package while satisfying the minimum distance between the pads may be provided.

### BRIEF DESCRIPTION OF THE DRAWINGS

FIGS. 1A and 1B are views for explaining a camera module in accordance with an exemplary embodiment.

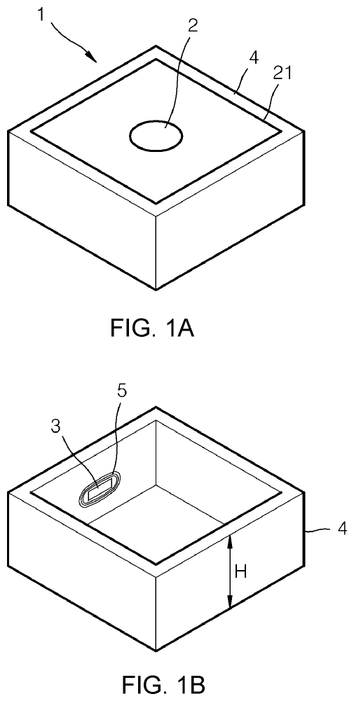

FIGS. 2A, 2B, 2C and 2D are views illustrating constraints in lens aperture of the camera module and size of the semiconductor package according to an embodiment.

FIG. 3 is a bottom view of a semiconductor package according to an embodiment of the present invention.

FIGS. 4A and 4B are views for explaining configuration of a terminal illustrated in FIG. 3.

FIG. 5 is a view for explaining a minimum distance between terminals according to an embodiment of the present invention.

FIG. 6 is a view for explaining a range of an angle between a first direction, in which a virtual straight radial line is directed, and a protruding direction of a protruding part of a terminal, through which the straight radial line passes, according to an embodiment of the present invention.

FIG. 7 is a bottom view of a semiconductor package according to another embodiment of the present invention.

FIGS. 8A and 8B are views for explaining a configuration of a terminal illustrated in FIG. 7.

### MODE FOR CARRYING OUT THE INVENTION

Hereinafter, embodiments of the present invention will be described with reference to the attached drawings. However, the present invention is not limited to embodiments described in this specification and may be implemented in various other forms. The terms used in this specification are intended to aid understanding of the embodiments and are not intended to limit the scope of the present invention. In addition, as used herein, singular forms include plural forms unless phrases clearly indicate the contrary.

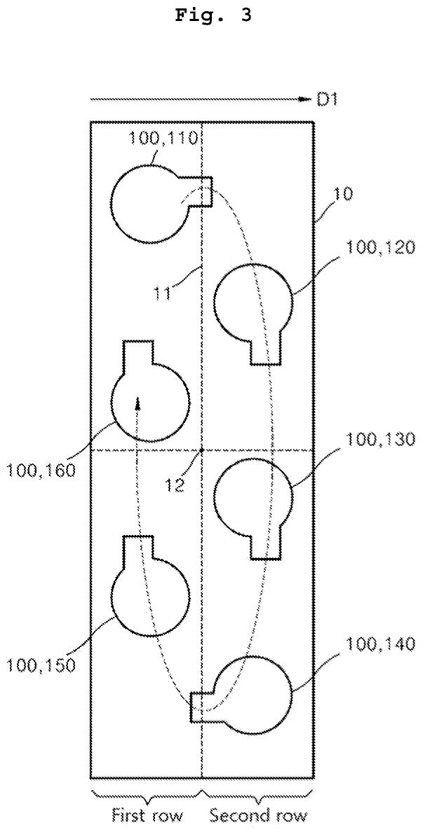

FIG. 3 is a bottom view of a semiconductor package according to an embodiment of the present invention.

A semiconductor package 10 may be a wafer-level chip-size package type having a plurality of terminals 100.

The semiconductor package 10 may have an elongated and narrow rectangular planar shape.

The plurality of terminals 100 may be provided in two columns arranged along a short-side direction D1 of the semiconductor package 10.

Here, a virtual division line that divides the plurality of terminals 100 in the semiconductor package 10 into the two columns (first column and second column) is indicated by reference number 11.

In addition, a center of gravity of the semiconductor package 10 is indicated by reference number 12.

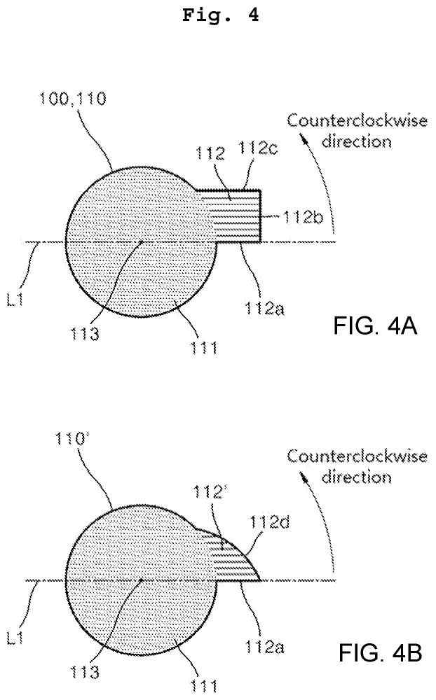

Each of the terminals 100 may include a circular body part and a protruding part extending outward from the body part. Here, the protruding part of each terminal 100 in the semiconductor package 10 may be disposed so that the protruding parts rotate as a whole in a clockwise direction. Hereinafter, the configuration of the terminal will be described with reference to FIG. 4.

FIG. 4 is a view for explaining a configuration of the terminal illustrated in FIG. 3.

FIG. 4A illustrates a configuration of a terminal according to a first embodiment, and FIG. 4B illustrates a configuration of a terminal according to a second embodiment.

First, the configuration of the terminal will be described based on FIG. 4A.

Each of terminals 100 and 110 may include a circular body part 111 and a protruding part 112 extending outward from the body part 111.

The protruding part 112 may include a first straight edge line 112a, a second straight edge line 112b, and a third straight edge line 112c.

An extension line L1 of the first straight edge line 112a may pass through the gravity center 113 of the body part 111.

The protruding part 112 may be disposed in a counterclockwise direction based on the first straight edge line 112a.

Here, the third straight edge line 112c may be parallel to the first straight edge line 112a, and one end point of the third straight edge line 112c may be connected to one point of the body part 111.

The second straight edge line 112b may be connected at a right angle to each of a point that is not connected to the body part 111 at both end points of the first straight edge line 112a and the other end point of the third straight edge line 112c. That is, an angle between the first straight edge line 112a and the second straight edge line 112b may be a right angle, and an angle between the second straight edge line 112b and the third straight edge line 112c may be a right angle.

Hereinafter, the configuration of the terminal will be described based on FIG. 4B.

Each of terminals 100 and 110 may include a circular body part 111 and a protruding part 112′ extending outward from the body part 111.

The protruding part 112′ may include a first straight edge line 112a and a fourth curved edge line 112d.

An extension line L1 of the first straight edge line 112a may pass through the gravity center 113 of the body part 111.

The protruding part 112′ may be disposed in a counterclockwise direction based on the first straight edge line 112a.

Here, one end point of the fourth curved edge line 112d may be connected to a point that is not connected to the body part 111 at both end points of the first straight edge line 112a, and the other end point of the fourth curved edge line 112d may be connected to one point of the body part 111.

Here, the fourth curved edge line 112d may be, for example, a parabola or a straight line, but is not limited thereto.

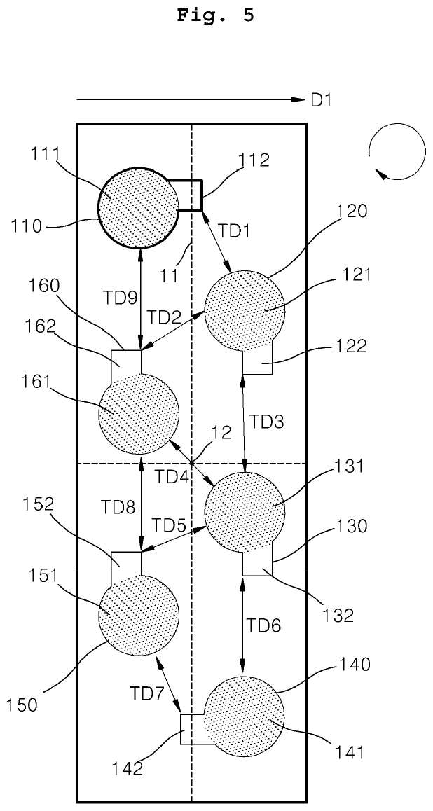

FIG. 5 is a view for explaining a minimum distance between terminals according to an embodiment of the present invention.

Pads on the PCB of the camera module (not shown) may be disposed to correspond to positions of the terminals 110 to 116 of the semiconductor package 10 illustrated in FIG. 5. Here, as described above, a minimum distance between the pads has to be ensured, and for this, a minimum distance between the terminals has to be also secured.

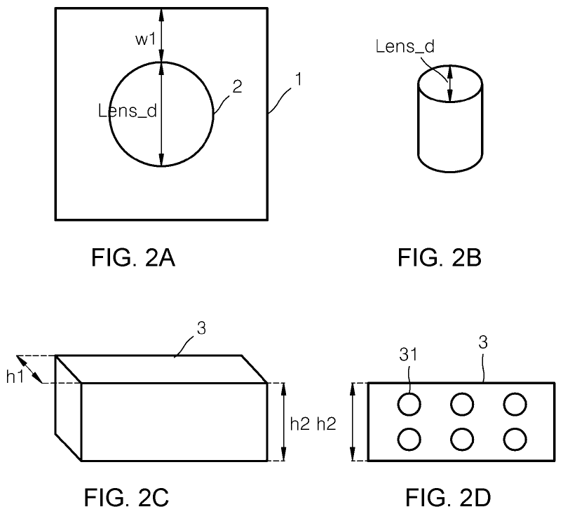

In the arrangement of the terminals (lead balls) as described above with reference to FIG. 2, there is a limitation in that the minimum distance between the terminals is not secured when an amount of lead increases. However, according to the present invention, as illustrated in FIG. 5, the terminals 110 to 116 may be disposed in a zigzag shape, and although the terminals having the protruding parts are used to increase in amount of lead, a minimum distance TD1 to TD9 between the terminals 110 to 116 may be secured.

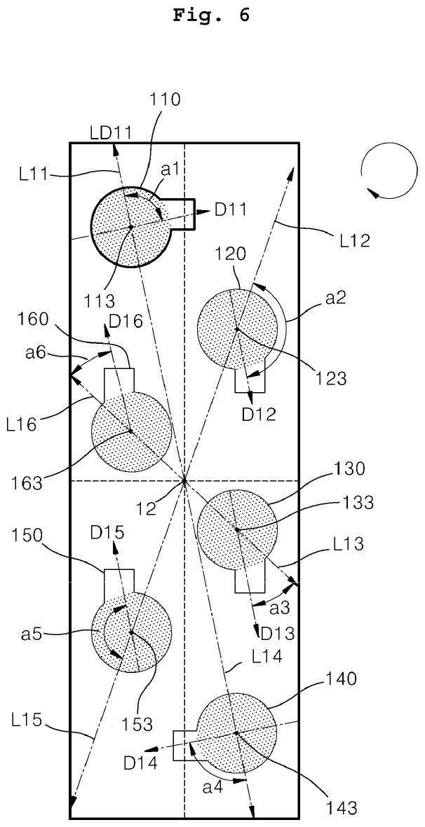

FIG. 6 is a view for explaining a range of an angle between a first direction, in which a virtual straight radial line is directed, and a protruding direction of a protruding part of a terminal, through which the straight radial line passes, according to an embodiment of the present invention.

Hereinafter, description will be made with reference to FIGS. 5 and 6 together.

Virtual linear radial lines L11 to L16 may be lines connected from the gravity center 12 of the semiconductor package 10 to gravity centers 113 to 163 of the bodies 111 to 161 of the plurality of terminals 110 to 160, respectively.

For example, the first virtual straight radial line L11 may be a line connected from the gravity center 12 of the semiconductor package 10 to the gravity center 113 of the body part 111 of the first terminal 110.

The second virtual straight radial line L12 may be a line connected from the gravity center 12 of the semiconductor package 10 to the gravity center 123 of the body part 121 of the second terminal 120.

The third virtual straight radial line L13 may be a line connected from the gravity center 12 of the semiconductor package 10 to the gravity center 133 of the body part 131 of the third terminal 130.

The fourth virtual linear radial line L14 may be a line connected from the gravity center 12 of the semiconductor package 10 to the gravity centers 143 of the body part 141 of the fourth terminal 140.

The fifth virtual straight radial line L12 may be a line connected from the gravity center 12 of the semiconductor package 10 to the gravity center 153 of the body part 151 of the fifth terminal 150.

The sixth virtual straight radial line L13 may be a line connected from the gravity center 12 of the semiconductor package 10 to the gravity center 163 of the body part 161 of the sixth terminal 160.

Here, an angle between the direction in which each of the virtual straight radial lines L11 to L16 and the protruding part of the terminal through which the straight radial line passes may be greater than about 45° and less than about 165°. Here, the protruding direction may be a direction from a point of the first straight edge line 112a of each of the protruding parts 112 and 112′, which is connected to the body part 111, to a point that is not connected to the body part 111.

For example, a first angle a1 between a first direction LD11, in which the first virtual straight radial line L11 is directed, and a protruding direction D11 of the protruding part 112 of the first terminal 110 passing through the first virtual straight radial line L11 may be greater than about than 45° and less than about 165°. For example, the first angle may be about 102°.

For example, a second angle a2 between a second direction LD12, in which the second virtual straight radial line L12 is directed, and a protruding direction D12 of the protruding part 122 of the second terminal 120 passing through the second virtual straight radial line L12 may be greater than about than 45° and less than about 165º. For example, the second angle may be about 161º.

For a third angle a3 between a third direction LD13, in which the third virtual straight radial line L13 is directed, and a protruding direction D13 of the protruding part 132 of the third terminal 130 passing through the third virtual straight radial line L13 may be greater than about than 45° and less than about 165°. For example, the third angle may be about 47°.

For example, a fourth angle a4 between a fourth direction LD14, in which the fourth virtual straight radial line L14 is directed, and a protruding direction D14 of the protruding part 142 of the fourth terminal 140 passing through the fourth virtual straight radial line L14 may be greater than about than 45° and less than about 165°. For example, the fourth angle may be about 102°.

For a fifth angle a5 between a fifth direction LD15, in which the fifth virtual straight radial line L15 is directed, and a protruding direction D15 of the protruding part 152 of the fifth terminal 150 passing through the fifth virtual straight radial line L15 may be greater than about than 45° and less than about 165°. For example, the fifth angle may be about 161°.

For example, a sixth angle a6 between a sixth direction LD16, in which the sixth virtual straight radial line L16 is directed, and a protruding direction D16 of the protruding part 162 of the sixth terminal 160 passing through the sixth virtual straight radial line L16 may be greater than about than 45° and less than about 165°. For example, the sixth angle may be about 47º.

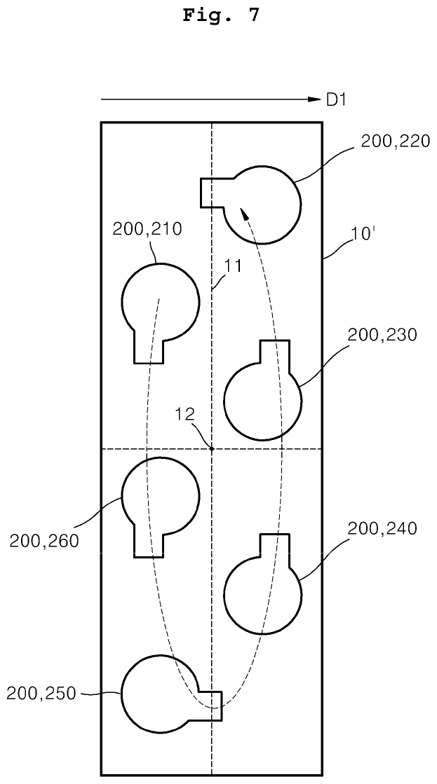

FIG. 7 is a bottom view of a semiconductor package according to another embodiment of the present invention.

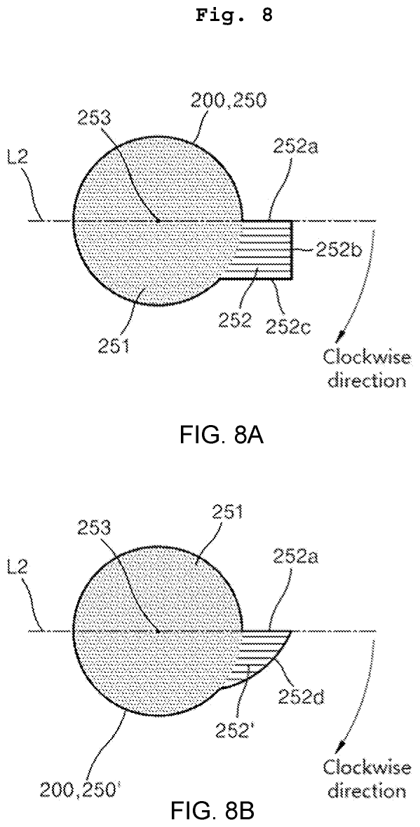

FIGS. 8A and 8B are views for explaining a configuration of a terminal illustrated in FIG. 7.

FIG. 8A illustrates a configuration of a terminal according to a third embodiment, and FIG. 8B illustrates a configuration of a terminal according to a fourth embodiment.

Hereinafter, description will be described with reference to FIGS. 3, 4, 7, and 8.

A difference between the semiconductor package 10′ of FIG. 7 and the semiconductor package 10 of FIG. 3 may be in shape of the terminals. That is, the protruding part 112 of the terminal 110 in FIG. 4 may be disposed in a counterclockwise direction based on the first straight edge line 112a, but the protruding part 252 of the terminal 250 in FIG. 8 may be disposed in a clockwise direction based on the straight edge 252a.

At this time, in FIG. 7, the protruding parts of the terminals 210 to 260 of the semiconductor package 10′ may be disposed so that the protruding parts rotate as a whole in the counterclockwise direction.

Referring to FIG. 8A, each of the terminals 200 and 250 may include a circular body part 251 and a protruding part 252 extending outward from the body part 251.

The protruding part 252 of the terminal 250 may include a first straight edge line 252a, a second straight edge line 252b, and a third straight edge line 252c.

An extension line L2 of the first straight edge line 252a may pass through a gravity center 253 of the body part 251.

The protruding part 252 may be disposed in a clockwise direction based on the first straight edge line 252a.

Here, the third straight edge line 252c may be parallel to the first straight edge line 252a, and one end point of the third straight edge line 252c may be connected to one point of the body part 251.

The second straight edge line 252b may be connected at a right angle to each of a point that is not connected to the body part 251 at both end points of the first straight edge line 252a and the other end point of the third straight edge line 252c. That is, an angle between the first straight edge line 252a and the second straight edge line 252b may be a right angle, and an angle between the second straight edge line 252b and the third straight edge line 252c may be a right angle.

Referring to FIG. 8B, each of the terminals 200 and 250 may include a circular body part 251 and a protruding part 252 extending outward from the body part 251.

The protruding part 252′ may include a first straight edge line 252a and a fourth curved edge line 252d.

An extension line L2 of the first straight edge line 252a may pass through a gravity center 253 of the body part 251.

The protruding part 252′ may be disposed in a clockwise direction based on the first straight edge line 252a.

Here, one end point of the fourth curved edge line 252d may be connected to a point that is not connected to the body part 251 at both end points of the first straight edge line 252a, and the other end point of the fourth curved edge line 252d may be connected to one point of the body part 251.

Here, the fourth curved edge line 252d may be, for example, a parabola or a straight line, but is not limited thereto.

In the embodiment of FIG. 7, a minimum distance between the terminals may be secured as in the embodiment of FIG. 5.

In addition, in FIG. 8, an angle between the direction, in which the virtual straight radial line is directed, and the protruding direction of the protruding part of the terminal, through which the straight radial line passes, may be greater than about 45° and less than about 165°.

Here, the protruding direction may be a direction from a point of the first straight edge line 252a of each of the protruding parts 252 and 252′, which is connected to the body part 251, to a point that is not connected to the body part 251.

In the present invention described above, the reason in which the terminals (and the pads having the same shape as the terminals) in the counterclockwise or clockwise direction is to secure the minimum distance between the terminals (and the pads having the same shape as the terminals).

In addition, when the shape of one pad is determined, other pads (and/or terminals) have to be provided in the same shape. This is because the amount of lead attached to each pad has to be managed equally.

according to the foregoing embodiments of the present invention, those in the technical field of the present invention will be able to easily make various changes and modifications without from the essential departing characteristics of the present invention. The contents of each claim in the patent claims can be combined with other claims without reference within the scope that can be understood through this specification.

1. A semiconductor package, which is provided as a wafer-level chip-size package type semiconductor package (10) having a plurality of terminals (100),
wherein the semiconductor package has an elongated and narrow rectangular planar shape,
the plurality of terminals are arranged in two columns along a short-side direction (D1) of the semiconductor package, and
each of the terminals comprises a circular body part (111) and a protruding part (112) extending outward from the body part.

2. The semiconductor package of claim 1, wherein the protruding part comprises a first straight edge line (112a), and an extension line (L1) of the first straight edge line passes through a gravity center (113) of the body part, and
the protruding part is disposed in a counterclockwise direction based on the first straight edge line.

3. The semiconductor package of claim 1, wherein the protruding part comprises a first straight edge line, and an extension line of the first straight edge line passes through a gravity center of the body part, and
the protruding part is disposed in a clockwise direction based on the first straight edge line.

4. The semiconductor package of claim 2, wherein, in a virtual straight radial line (L11) connected from a gravity center (12) of the semiconductor package to the gravity center of the body part of each of the plurality of terminals,
an angle between a first direction (LD11), in which the virtual straight radial line is directed, and a protruding direction of the protruding part of the terminal, through which the straight radial line passes, is greater than about 45° and less than about 165°.

5. The semiconductor package of claim 2, wherein the protruding part further comprises a second straight edge line (112b) and a third straight edge line (112c),
wherein the third straight edge line is parallel to the first straight edge line,
one end point of the third straight edge line is connected to one point of the body part, and
the second straight edge line is perpendicularly connected to each of a point of both end points of the first straight edge line (112a), which is not connected to the body part, and the other end point of the third straight edge line (112c).

6. The semiconductor package of claim 2, wherein the protruding part further comprises a fourth curved edge line (112d),
wherein one end point of the fourth curved edge line is connected to a point of both end points of the first straight edge line, which is not connected to the body part, and the other end point of the fourth curved edge line is connected to one point of the body part.

7. The semiconductor package of claim 1, wherein the protruding part (112) of at least one terminal (110) of the plurality of terminals is configured to invade a virtual division line (11) that divides the plurality of terminals into two columns in the semiconductor package.

8. The semiconductor package of claim 1, wherein the protruding part (112) of at least one terminal (110) of the plurality of terminals is configured to overlap a virtual division line (11) that divides a short width of the short width and a long width of the semiconductor package into ½.
